(19) United States
(12) Patent Application Publication
(10) Pub. No.: US 2010/0309641 A1
(43) Pub. Date: Dec. 9, 2010

(54) INTERPOSER SUBSTRATE, LSI CHIP AND INFORMATION TERMINAL DEVICE USING THE INTERPOSER SUBSTRATE, MANUFACTURING METHOD OF INTERPOSER SUBSTRATE, AND MANUFACTURING METHOD OF LSI CHIP

(75) Inventors: Hanae Hata, Yokohama (JP); Masato Nakamura, Yokohama (JP); Masaki Nakanishi, Tokyo (JP); Nobuhiro Kinoshita, Tokyo (JP)

Correspondence Address: MATTINGLY & MALUR, P.C., 1800 DIAGONAL ROAD, SUITE 370, ALEXANDRIA, VA, 22314, US

(73) Assignee: RENESAS TECHNOLOGY CORP., Tokyo (JP)

(21) Appl. No.: 12/521,602

(22) PCT Filed: Mar. 21, 2008
(86) PCT No.: PCT/JP2008/055215

§ 371 Date: Aug. 13, 2009

(30) Foreign Application Priority Data
Mar. 23, 2007 (JP) 2007-077766

(51) Int. Cl. H05K 7/00; H01L 23/488; H01L 21/60; H05K 1/09; H05K 3/10

(52) U.S. Cl. 361/783; 257/737; 438/121; 174/257; 205/118; 257/E21.511; 257/E23.023

(57) ABSTRACT

A method of forming narrow-pitch flip-chip bonding electrodes and wire bonding electrodes at the same time is provided so as to reduce the cost of a substrate. In addition, a low-cost solder supply method and a flip-chip bonding method to a thin Au layer are provided. A stacked layer of a Cu layer 23 and a Ni layer 24 is employed as the electrode structure, and an Au layer 25 is plated on the outer periphery thereof. In the flip-chip bonding, dissolution of Au into the solder is minimized by employing a metal jet system in the soldering to the electrodes, so that the formation of Sn—Au having a high melting point is prevented, and at the same time, the wire-bondable Au layer 25 is ensured.

### TECHNICAL FIELD

The present invention relates to a semiconductor device having the System in Package (SiP) structure, in which a plurality of chips are packaged in one package.

### BACKGROUND ART

In order to meet the diversified consumer needs, electronics devices have been equipped with more and more functions. At the same time, downsizing and thickness reduction of portable devices have also been advanced. Therefore, the needs for the system LSI capable of high density packaging with high performance and advanced functions have been increased. Previously, many techniques for the integration of large-scale circuits in one chip called SOC (System On a Chip) have been developed. However, with the increase in the scale of integrated circuits, for example, the cost of masks is increased and designing thereof becomes difficult due to the miniaturization, and as a result, it becomes difficult to follow the various requirements of customers in a short period of time. Accordingly, as effective means to compensate for that, the technique called SiP (System in Package) that accommodates a plurality of LSI chips and memories in one package has been developed, and it has become an important technique that supports the functional advancement, downsizing, and thickness reduction.

The way of arranging the LSI chips by the SiP technique is different depending on the use thereof. In order to realize a high performance, high quality, and highly reliable package to be used in a network environment product or the like, the packaging method of a flat arrangement type is employed in many cases. In order to realize an ultra small and thin package to be used in a portable phone, a digital camera, or the like, the packaging method of a stack type in which LSI chips, memories, and others are stacked is employed in many cases.

FIG. 11 shows a structural example of a package 1 of the stack type.

In the packaging of the package 1 of the stack type, a first chip 3 is bonded on an interposer substrate 2 by flip-chip bonding electrodes 4. After the bonding, a resin called underfill 5 is filled between the interposer substrate 2 and the first chip 3.

After the underfill 5 is filled, a second chip 7 is placed on a rear surface of the first chip 3, that is, on a top surface thereof (the surface on the opposite side of the surface bonded to the interposer substrate 2, and hereinafter, “top surface” will be used to mean “the surface on the opposite side of the previously bonded surface”) by an adhesive agent 6, and electrodes 103 for wire bonding on the second chip 7 and wire-bonding electrodes 101 formed on the interposer substrate 2 are mutually wire-bonded by gold wires 111.

Furthermore, a third chip 11 is stacked on a top surface of the second chip 7 by an adhesive layer 10 which also serves as a spacer. Then, wire-bonding electrodes 102 and wire-bonding electrodes 104 are mutually wire-bonded and connected by gold wires 112. Thereafter, molding by a resin 12 is carried out, and solder balls 13 for external connection are attached to the surface of the interposer substrate 2 that is on the opposite side of the surface on which the chips are stacked. In the current packaging method of the stack type, a package in which chips are stacked in about five levels has been put into practical use. In addition, the structure in which a plurality of chips are arranged flatly on the first chip 3 or the second chip 7 has also been put into practical use.

The requirements for functional advancement will be further increased from here on, whereas the package size has to be downsized and thinned.

A multilayer build-up substrate or the like is mainly used as the interposer substrate 2 used in the above-described SiP packaging of the stack type. An overview of the electrode arrangement on the surface of the interposer substrate 2 is shown in FIG. 12.

On the chip bonding surface of the above-described interposer substrate 2, the flip-chip bonding electrodes 4 and the electrodes for wire bonding (hereinafter, “wire bonding electrodes”) 101 and 102 are formed. The wire bonding electrodes 101 and 102 are formed outside the flip-chip bonding electrodes 4. A solder resist layer 15 is formed on the surface of the substrate, and openings 16 of the solder resist are provided in the peripheries of the flip-chip bonding electrodes 4 and the wire bonding electrodes 101 and 102.

The electrode material of the wire bonding electrodes 101 and 102 has an electrode structure in which a gold (Au) layer (hereinafter, Au layer) is provided on a nickel (Ni) layer (hereinafter, Ni layer). This structure is employed for the reason that the Au layer is needed on the outermost surface in order to ensure the connectivity to the gold wires and the Ni layer is needed to ensure the strength against the pressure at the time of the bonding.

Meanwhile, the flip-chip bonding electrodes 4 are made of copper (Cu). This is because the flip-chip bonding electrodes are required to have soldability. As a method for supplying solder to the flip-chip bonding electrodes 4 having narrow pitches, for example, the method in which solder paste is supplied to the electrodes by printing/heating and then cleaning is carried out has been employed, or the method in which after a sticky layer is formed on the Cu electrode surface by a special solvent, solder powder is adhered thereon, and then heating and cleaning are carried out has been employed. These methods include a heat treatment at about 240° C. or higher for about 30 seconds. This is because, since the melting point of tin (Sn)-Silver (Ag) based lead-free solder is around 220° C., the heating at a temperature that is higher than the melting point by around 20° C. is required to melt them and carry out soldering.

FIG. 13A to 13J show the conventional formation process of an electrode pattern of a surface layer.

First, a copper seed layer 39 is formed by electroless copper plating on a base substance 35 prepared in the process before the surface layer pattern formation process (FIG. 13A). A pattern of a plating resist 40 is formed on the seed layer 39 by printing, exposure, development, and others (FIG. 13B).

Next, a Cu layer 36 is formed by electroplating using the seed layer 39 (FIG. 13C). Then, after removing the plating resist 40 (FIG. 13D), a part of the seed layer 39 on which the Cu layer 36 is not formed is removed (FIG. 13E).

Furthermore, a solder resist is supplied to the entire surface of the interposer substrate by printing or laminating and a pattern of a solder resist layer 34 is formed by performing exposure and development (FIG. 13F). Thereafter, a plating resist 91 is formed on the region where the Cu layers are to be left (FIG. 13G), and a Ni layer 37 is formed on the part of the Cu layer 36 on which the plating resist 91 is not present (FIG. 13H). Furthermore, an Au layer 38 is formed by plating process (FIG. 131). Then, the plating resist 91 is removed (FIG. 13J).

Non-Patent Document 1: Journal of Japan Institute of Electronics Packaging vol. 8, No. 7, November (2006) pp. 536 to 541

### DISCLOSURE OF THE INVENTION

### Problem to be Solved by the Invention

As described above, in the interposer substrate 2, the two types of electrodes have to be formed on the surface layer, and so-called two types of plating processes are required. Consequently, manufacturing process becomes complicated and expensive, and this is one of the factors that inhibit the cost reduction of SiP. Moreover, the Cu electrodes of the flip-chip bonding electrodes 4 have the problem in the wettability of solder affected by the surface oxidation. In addition, the pitches of electrodes are narrowed along with the downsizing, density increase, and functional advancement, and there is a request to realize the pitch of 40 μm or less particularly in the flip-chip bonding electrodes 4 in the future. However, narrowing the pitch on the substrate directly leads to the increase of the price of the interposer substrate.

Moreover, in the supply of the solder to the flip-chip bonding electrodes 4, the material cost is increased because special solder paste or the like for narrow pitches is used. Also, since the processes of electrode surface treatment, cleaning, and others become longer, the processing cost is increased and this is an obstacle for the cost reduction.

Therefore, it is considered to simplify the manufacturing process by employing the metallization process of the stacked layer of a Ni layer and an Au layer as the formation of the flip-chip bonding electrodes 4 similarly to the wire bonding electrodes 101 and 102.

However, if the flip-chip bonding electrodes 101 and 102 are formed to have the same structure as the wire bonding electrodes 4, since a thick Ni layer is required for wire bonding, width of the electrodes becomes bigger in the lateral direction when the formation method like that of FIG. 13F is employed. When the variations which are inevitably generated in a nickel plating process are also taken into consideration, it has been difficult to apply the electrode structure of the stacked layer of a Ni layer and an Au layer to the narrow-pitch electrodes for flip-chip bonding.

Furthermore, in order to wire-bond gold wires, a thick Au layer is required on the surface layer. However, since the flip-chip bonding of the flip-chip bonding electrodes 4 and the solder on the interposer substrate 2 is made through the heat treatment at about 240° C. or higher for about 30 seconds as described above, thick gold melts into the solder during the heating, so that the melting point of the solder increases. Thus, the flip-chip bonding of the chip 3 and the solder becomes difficult.

In view of the foregoing, an object of the present invention is to provide a method of forming narrow-pitch flip-chip bonding electrodes and wire bonding electrodes at the same time, thereby reducing the cost of the substrate.

Also, another object of the present invention is to provide a low-cost method of supplying solder to a thin Au layer and a flip-chip bonding method.

The above and other objects and novel characteristics of the present invention will be apparent from the description of this specification and the accompanying drawings.

### Means for Solving the Problems

The typical ones of the inventions disclosed in this application will be briefly described as follows.

An interposer substrate according to the present invention comprises: a flip-chip bonding electrode formed of a stacked layer of a copper (Cu) layer and a nickel (Ni) layer; and a wire bonding electrode formed of a stacked layer of a copper (Cu) layer and a nickel (Ni) layer, wherein surfaces of the flip-chip bonding electrode and the wire bonding electrode, the surfaces not being in contact with a base substance or a solder resist, are covered by gold (Au).

The Au of the interposer substrate may be supplied by electroless plating.

Further, in this interposer substrate, the Cu layer of the flip-chip bonding electrode and the Cu layer of the wire bonding electrode are formed to have an approximately same thickness, and the Ni layer of the flip-chip bonding electrode and the Ni layer of the wire bonding electrode are formed to have an approximately same thickness.

Further, a LSI chip employing a SiP (System in Package) can be manufactured by using this interposer substrate. Also, in the manufacturing process thereof, a metal jet system is preferably used to supply solder for flip-chip bonding of the interposer substrate.

The application of the LSI chip manufactured in the above-described manner to an information terminal device is also intended.

Meanwhile, manufacturing methods are also taken into consideration in the present invention.

A manufacturing method of an interposer substrate which comprises: a flip-chip bonding electrode formed of a stacked layer of a copper (Cu) layer and a nickel (Ni) layer; and a wire bonding electrode formed of a stacked layer of a copper (Cu) layer and a nickel (Ni) layer according to the present invention comprises: a seed layer preparation step for preparing a seed layer; a plating resist formation step for forming a plating resist on the seed layer; a Cu layer formation step for forming a Cu layer by utilizing the seed layer; a Ni layer formation step for forming and stacking a Ni layer on the Cu layer; a seed layer removal step for removing a part of the seed layer on which the Ni layer and the Cu layer are not stacked; a solder resist formation step for forming a solder resist layer; and an Au layer formation step for supplying gold (Au) onto exposed surfaces of the Cu layer and the Ni layer, wherein the flip-chip bonding electrode and the wire bonding electrode are formed without repeating each of the steps.

This manufacturing method of the interposer substrate preferably comprises a plating resist removal step for removing the plating resist after the Ni layer formation step.

Also, a packaging method of a LSI chip using the above-described interposer substrate comprises: a solder supply step for supplying solder to the flip-chip bonding electrode by a metal jet system; a first chip bonding step for thermocompression-bonding a first chip to the flip-chip bonding electrode; a first chip fixing step for filling a resin between the first chip and the interposer substrate and hardening the resin; a second chip placing step for placing a second chip on the first chip; a second chip wire bonding step for wire bonding the second chip and the wire bonding electrode; and a step of bonding a third or more chips by repeating similar steps to those for the bonding of the second chip in accordance with needs.

Also, another packaging method of a LSI chip using the above-described interposer substrate comprises: a solder supply step for supplying solder to the flip-chip bonding electrode by a metal jet system; a resin supply step for supplying a resin for fixing a first chip; a first chip bonding/fixing step for thermocompression-bonding the first chip to the flip-chip bonding electrode and hardening the resin; a second chip placing step for placing a second chip on the first chip; a second chip wire bonding step for wire bonding the second chip and the wire bonding electrode; and a step of bonding a third or more chips by repeating similar steps as those for the bonding of the second chip in accordance with needs.

### EFFECT OF THE INVENTION

The effects obtained by typical embodiments of the inventions disclosed in this application will be briefly described below.

When the above-described means is employed, the method of simultaneously forming the structures of narrow-pitched electrodes for flip-chip bonding and electrodes for wire bonding can be provided, and the cost reduction of the substrate can be realized. Moreover, by providing a solder supply method and a flip-chip bonding structure suitable for the substrate, the overall cost can be reduced.

### BRIEF DESCRIPTION OF THE DRAWINGS

FIG. 1 is a cross sectional view showing an electrode structure of an interposer substrate according to the present invention;

FIG. 2 is a drawing showing the interposer substrate according to the present invention;

FIG. 3 is a cross sectional view showing the structure of a group of electrodes of the interposer substrate according to the present invention;

FIGS. 4A to 4H are cross sectional views showing the manufacturing process of the electrodes according to the present invention;

FIG. 5 is a cross sectional view showing metal jet and the interposer substrate which is an application target thereof according to the present invention;

FIGS. 6A and 6B are cross sectional views showing the structure of the electrodes after the solder supply according to the present invention;

FIG. 7 is a cross sectional view showing the structure of a bonding part when a chip is flip-chip bonded to the interposer substrate after the solder supply according to the present invention;

FIG. 8 is a drawing showing a type of an electrode shape according to the present invention;

FIG. 9 is a cross sectional view showing the structure of a bonding part when a chip is flip-chip bonded to an interposer substrate after the solder supply according to the present invention;

FIG. 10 is a cross sectional view showing the structure of a bonding part when a chip of a package using no Au bump is flip-chip bonded to an interposer substrate after the solder supply according to the present invention;

FIG. 11 is a cross sectional view showing a structural example of a package of a stack type;

FIG. 12 is an example of a general interposer substrate; and

FIGS. 13A to 13J are drawings showing the manufacturing process of electrodes relating to a conventional interposer substrate.

### BEST MODE FOR CARRYING OUT THE INVENTION

Hereinafter, a specific embodiment of the present invention will be described with reference to drawings.

(Electrode Formation of Interposer Substrate)

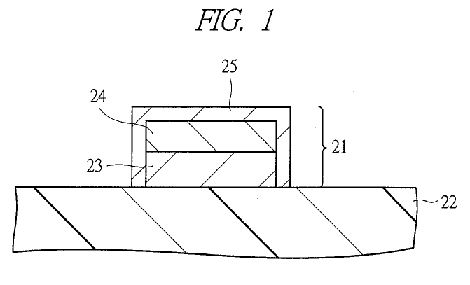

FIG. 1 is a cross sectional view showing the structure of an electrode 21 which is used as both a flip-chip bonding electrode and a wire bonding electrode according to the present invention.

In the electrode 21, a copper layer (hereinafter, Cu layer) 23 and a Ni layer 24 are formed on a base substance 22. The Ni layer 24 is formed on the Cu layer 23, but nickel does not adhere to side surfaces of the Cu layer 23. Therefore, thickening of the electrode in the lateral direction can be prevented, and the electrode can be applied also to narrow-pitch electrodes for flip-chip bonding. Moreover, the problem of surface oxidation is not caused because an Au layer 25 is formed on a side surface portion of the Cu layer 23 and on a top portion and a side surface portion of the Ni layer 24, and the wettability can be improved.

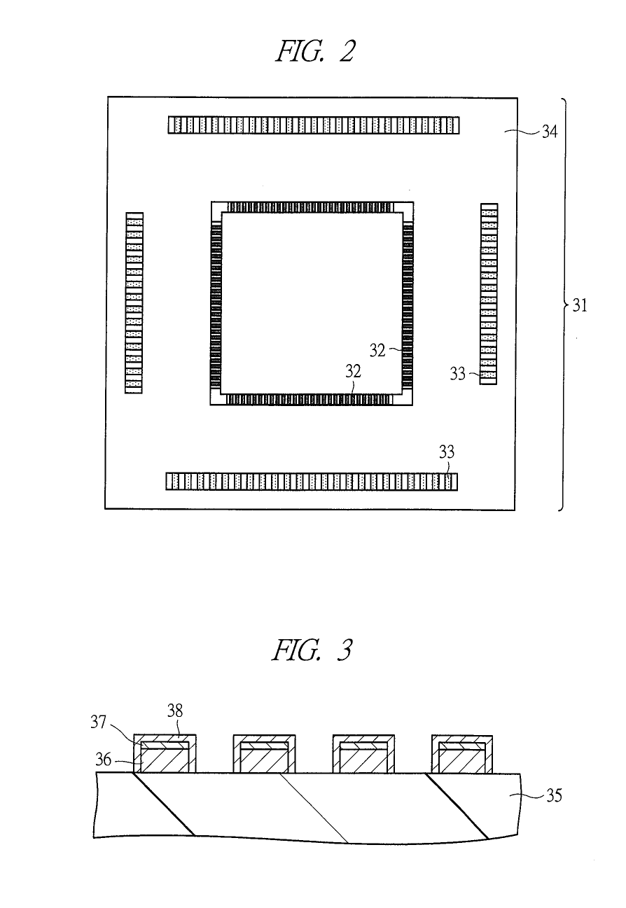

Next, positional relations in the case where the electrode of FIG. 1 is disposed on an actually-used interposer substrate 31 will be described with reference to FIG. 2.

A number of flip-chip bonding electrodes 32 and wire bonding electrodes 33 required for bonding are respectively provided on the interposer substrate 31 of FIG. 2.

It is presupposed in this case that the narrowest pitch among the pitches between the flip-chip bonding electrodes 32 is 60 μm and the electrode width thereof is 30 μm. In addition, in the peripheries of the flip-chip bonding electrodes, openings of a solder resist layer 34 are provided.

On the other hand, the electrode width of the wire bonding electrode 33 is 100 μm, and solder resist openings are provided in the peripheries thereof.

FIG. 3 shows a cross sectional view of the electrodes of the same type, which are either the flip-chip bonding electrodes 32 or the wire bonding electrodes 33. The flip-chip bonding electrodes 32 and the wire bonding electrodes 33 have the same structure, and it is presupposed that the thickness of the Cu layer 36 on the base substance 35 is 15 μm, the thickness of the Ni layer 37 thereon is 5 μm, and the thickness of the Au layer 38 on the surface is 1 μm.

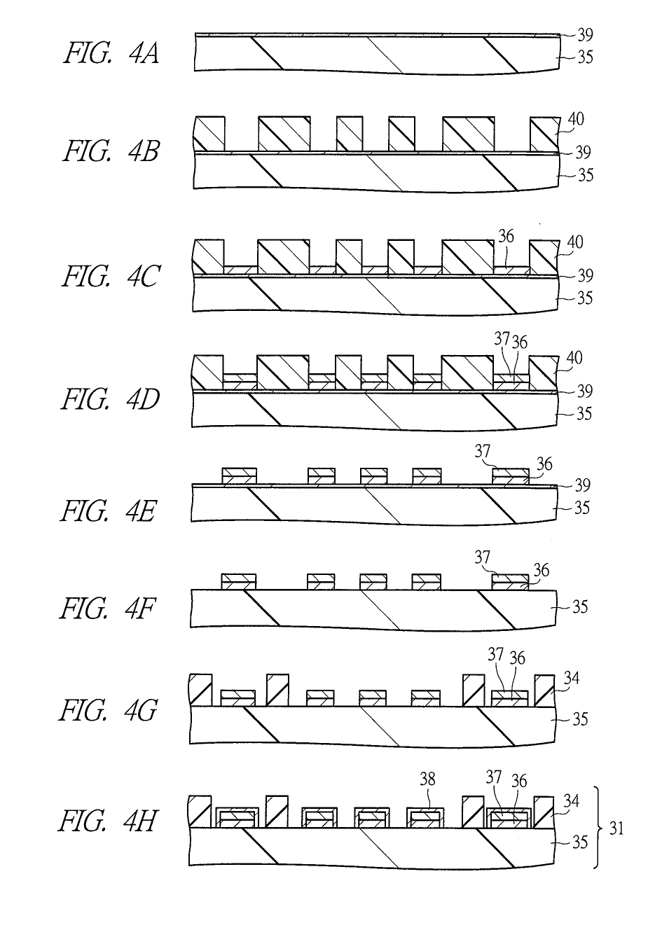

FIGS. 4A to 4H show the formation process of the electrode pattern of the surface layer. The formation of the electrodes will be described with reference to FIGS. 4A to 4H.

First, a copper seed layer 39 is formed by electroless copper plating on the base substance 35 prepared in the process before the surface layer pattern formation process (FIG. 4A). A pattern of a plating resist 40 is formed on the seed layer 39 by printing, exposure, development, and others (FIG. 4B).

Next, the Cu layer 36 is formed by electroplating utilizing the seed layer 39 (FIG. 4C), and the Ni layer 37 is further formed on the Cu layer 36 by electroplating (FIG. 4D). By this means, it is possible to prevent the Ni layer 37 from spreading to the side of the Cu layer 36.

After completing the formation of the Ni layer 37 which does not spread to the side of the Cu layer 36, the unnecessary plating resist 40 is eliminated (FIG. 4E). In addition, after the elimination of the plating resist 40, the seed layer 39 is removed (FIG. 4F).

Furthermore, a solder resist is supplied to the entire surface of the interposer substrate by printing or laminating and a pattern of the solder resist layer 34 is formed by performing exposure and development (FIG. 4G).

Lastly, the Au layer 38 having a thickness of about 1 μm is supplied by electroless plating (FIG. 4H). By this means, the surfaces of the electrodes not in contact with the base substance and the solder resist are covered by the Au layer.

When the flip-chip bonding electrodes and the wire bonding electrodes are formed in the above-described manner, both the electrodes can be formed at the same time by the same process. As a result, the thicknesses of the Cu layer 36, the Ni layer 37, and the Au layer 38 of the flip-chip bonding electrodes and the wire bonding electrodes become approximately the same.

Moreover, by virtue of the presence of the plating resist 40, the Ni layer 37 is not thickened in the lateral direction, and the electrode can be applied to the narrow-pitch wiring.

Although the method shown herein is an example, the wire bonding electrodes 32 and the flip-chip bonding electrodes 33 can be formed at a time and the cost of the substrate can be reduced in this method.

(Solder Discharge)

Next, soldering to the interposer substrate 31 in the case where SiP having a plurality of chips mounted in one package is to be formed by using the above-described interposer substrate 31 will be described.

In the soldering in the present invention, as the presupposed supplying method of solder to the Au layer of the flip-chip bonding electrodes, a predetermined amount of solder is supplied to each of the electrodes by a metal jet system. FIG. 5 is a schematic drawing showing a supplying method of the solder by the metal jet system in the present invention.

The schematic drawing of FIG. 5 includes metal jet equipment 51 for carrying out the metal jet process and the interposer substrate 31 to be processed. The plurality of flip-chip bonding electrodes 32 to which solder is to be supplied are disposed on the interposer substrate 31.

On the other hand, the metal jet equipment 51 has a head 59 for supplying the solder and a stage 58. The head 59 includes a tank 52 which stores the solder, a heater 53, a piezoelectric actuator 54, a diaphragm 55, a nozzle 56, and others.

The tank 52 is the part which retains the solder to be discharged. Note that, unless otherwise particularly stated in the description below, the solder to be used is presupposed to be Sn-3.5 mass % Ag (melting point: 221° C.)

The heater 53 is a heating device for heating the solder retained in the tank 52 to a predetermined temperature equal to or higher than the melting point and maintaining the solder in a dischargeable state. Herein, the temperature of the solder in the tank is presupposed to be 260° C.

The piezoelectric actuator 54 is an element which is displaced when a voltage is applied. Also, the diaphragm 55 is a vibrating plate. When the piezoelectric actuator is operated, the diaphragm 55 is pressed, and the solder in the tank 52 is discharged.

The nozzle 56 is a discharge port for discharging the solder.

The stage 58 is the part on which the interposer 31 is disposed and, it can carry out the heating.

Next, operation of the metal jet equipment 51 will be described.

The interior of the tank 52 is heated by the heater 53 to the predetermined temperature equal to or higher than the melting point of the solder. When a control unit (not shown) applies a voltage, the piezoelectric actuator 54 is displaced so as to press the diaphragm 55. By this means, the molten solder is discharged from the nozzle 56, so that a constant amount of a molten solder droplet 57 is ejected to the flip-chip bonding electrode 32 to be a target. In this discharge, a N₂ atmosphere is desirably used in order to prevent the oxidation of the molten solder droplet 57.

After the molten solder droplet 57 is discharged to the flip-chip bonding electrode 32 to be a target, the temperature of the molten solder droplet 57 eventually falls below the melting point, and the droplet solidifies.

Then, the control unit (not shown) moves either the head 59 or the stage 58 so as to move to the position of a next electrode, and supply of the solder is continued.

Herein, it is presupposed that the solder is discharged vertically when viewed from the packaging surface of the interposer substrate 31. However, the solder droplet 57 can be ejected from a lateral side by vertically placing the interposer substrate 31.

Furthermore, solder supplying performance per unit time can be improved by preparing a plurality of heads 59. Also, the atmosphere has been described above as the N₂ atmosphere, but an inert gas, a reductive gas such as H₂, and an atmosphere using these gases in combination may be used. If the wettability is excellent, the atmospheric air is not problematic.

(Electrode Structure after Solder Discharge)

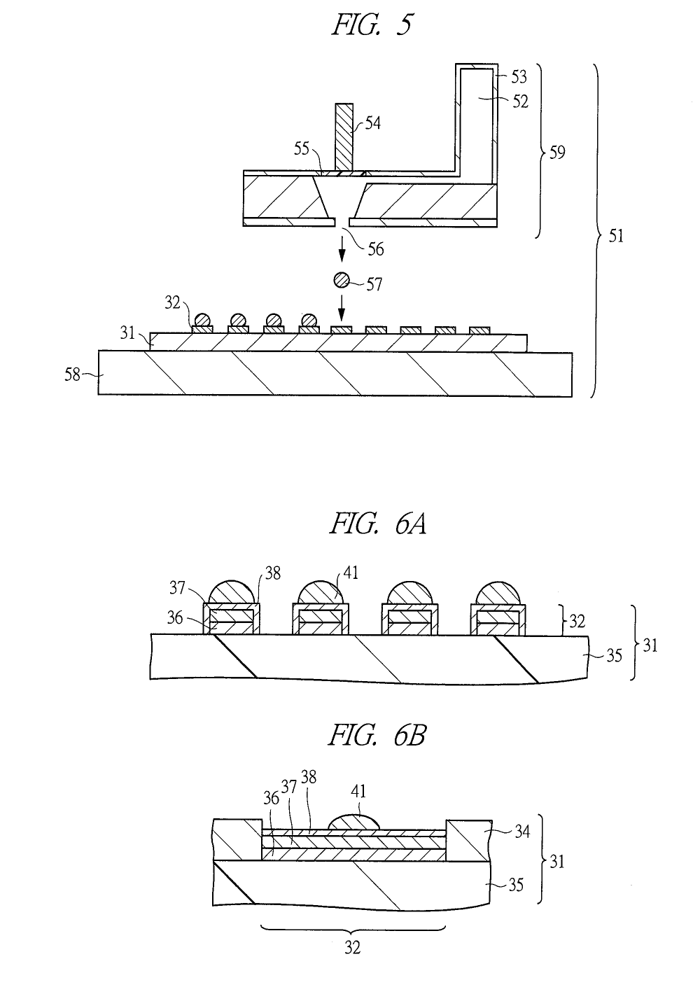

FIGS. 6A and 6B are cross sectional views showing the electrode structure after the solder discharge. FIG. 6A is a cross sectional view in the short-side direction of the electrode, and FIG. 6B is a cross sectional view in the longitudinal direction of the electrode.

Under the conditions described above, the droplet of the molten solder is supplied on the Au layer on the surface layer and forms a semispherical solder layer. Then, although gold slightly melts into the solder, the Au layer sufficiently remains. Thereafter, a chip on which Au bumps are formed is to be flip-chip bonded thereon.

(Process of Flip-Chip Bonding and Thereafter)

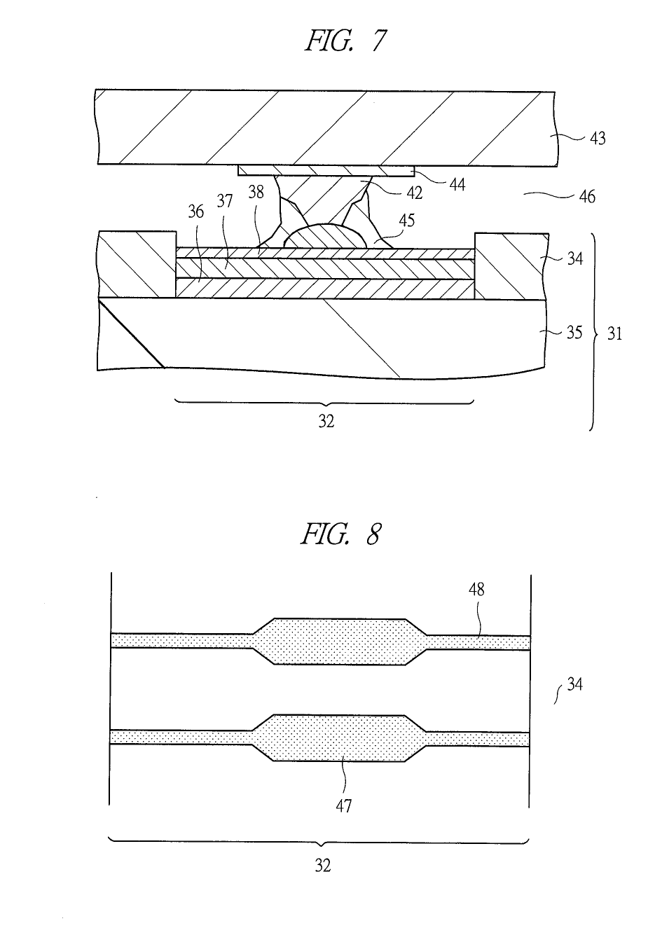

FIG. 7 shows the structure of a bonding part in the case where the interposer substrate 31 and a chip 43 are flip-chip bonded after solder supply.

An Au bump 42 is formed on the above-described chip 43, and an aluminum electrode (hereinafter, Al electrode) 44 on the chip 43 and the flip-chip bonding electrode 32 on the interposer substrate 31 are aligned and thermocompression-bonded, so that the solder 41 wicks up to the Au bump 42 formed on the Al electrode 44, and the Al electrode 44 of the chip 43 and the flip-chip bonding electrode 32 on the interposer substrate 31 are bonded to each other via the Au bump 42. Then, a resin 46 is filled between the interposer substrate 31 and the chip 43 and hardened.

Note that, in the process of the thermocompression bonding, the solder wicking may be improved by using ultrasonic waves in combination.

Furthermore, it is also possible to harden the resin simultaneously with the bonding of the Au bump 42 and the solder 41 by utilizing the heat thereof by previously supplying the resin in the vicinity of the center of the region where the chip 43 is to be bonded before the flip-chip bonding of the chip 43.

After the flip-chip packaging, a second chip and a third chip are packaged by wire bonding by Au wires as shown in FIG. 11. At this time, the wire bonding can be carried out without any problem by the electrodes having the structure shown in FIG. 1.

Then, heating for the mold resin hardening and heating to 240° C. for the soldering of external terminals are carried out, but the bonding part inside the flip-chip portion is not damaged by re-melting. The external terminals in this case are soldered by using solder balls of Sn-3 mass % Ag-0.5 mass % Cu (melting point: 217° C.)

When the electrodes obtained by forming a Ni layer on Cu and then forming an Au layer in the periphery thereof are used as the electrodes for wire bonding and flip-chip bonding in the above-described manner, the wire bonding and the flip-chip bonding using solder can be carried out without any problem, and the cost of the narrow-pitch substrate can be reduced.

In the above-described embodiment, the shape of the electrode for flip-chip bonding is rectangular. However, a part 47 to be bonded to an Au bump may have a laterally-expanded shape as shown in FIG. 8 so that wettability of the solder at the center part is improved. Moreover, in this case, the effect of preventing the solder from flowing in the direction of leading lines in the flip-chip bonding can be obtained.

Although the chips are stacked in the above-described embodiment, a part or all of the chips may be arranged flatly in the package.

### Application Example 1 of the Present Invention

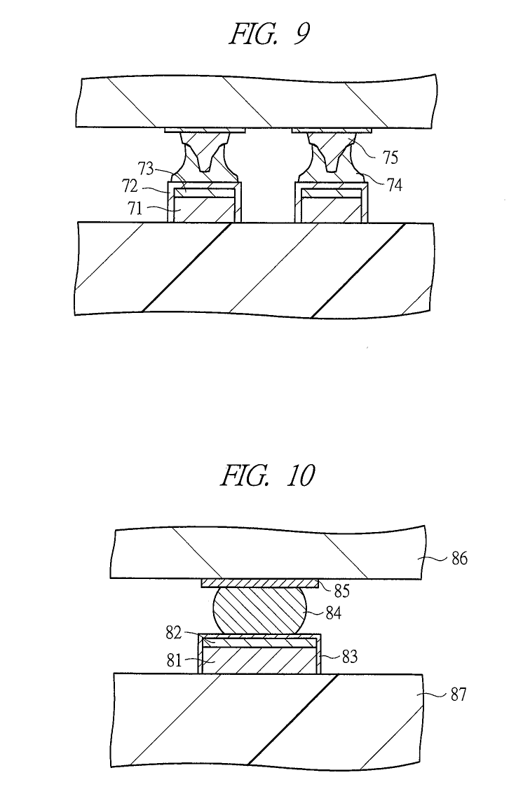

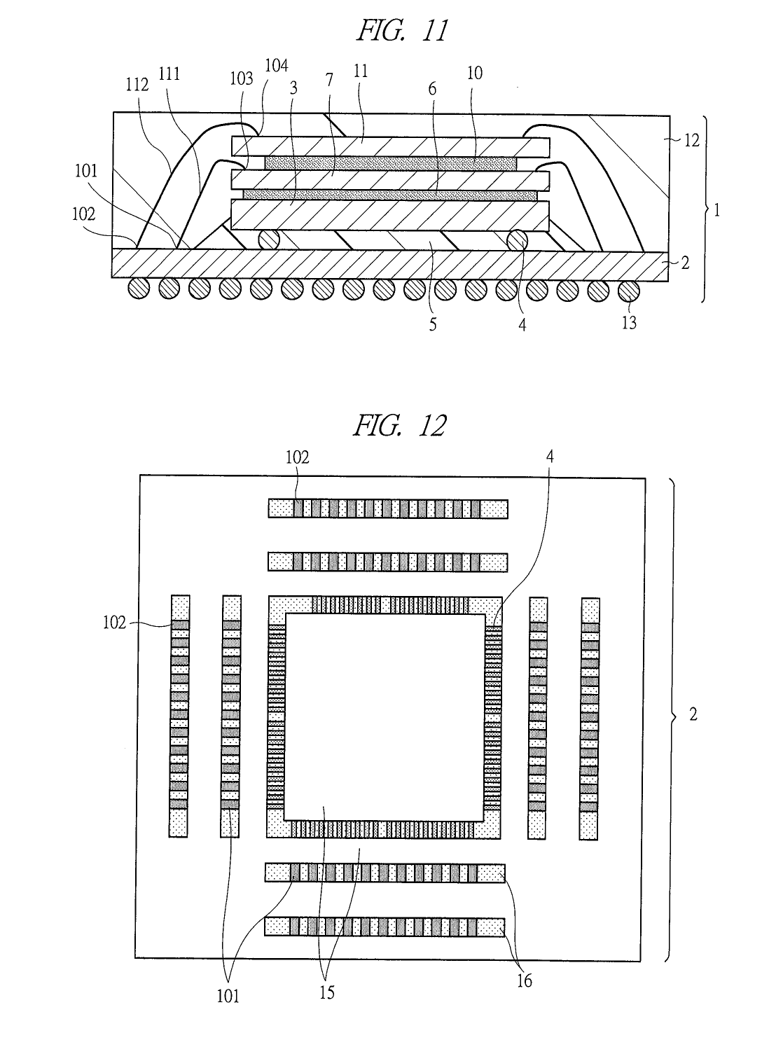

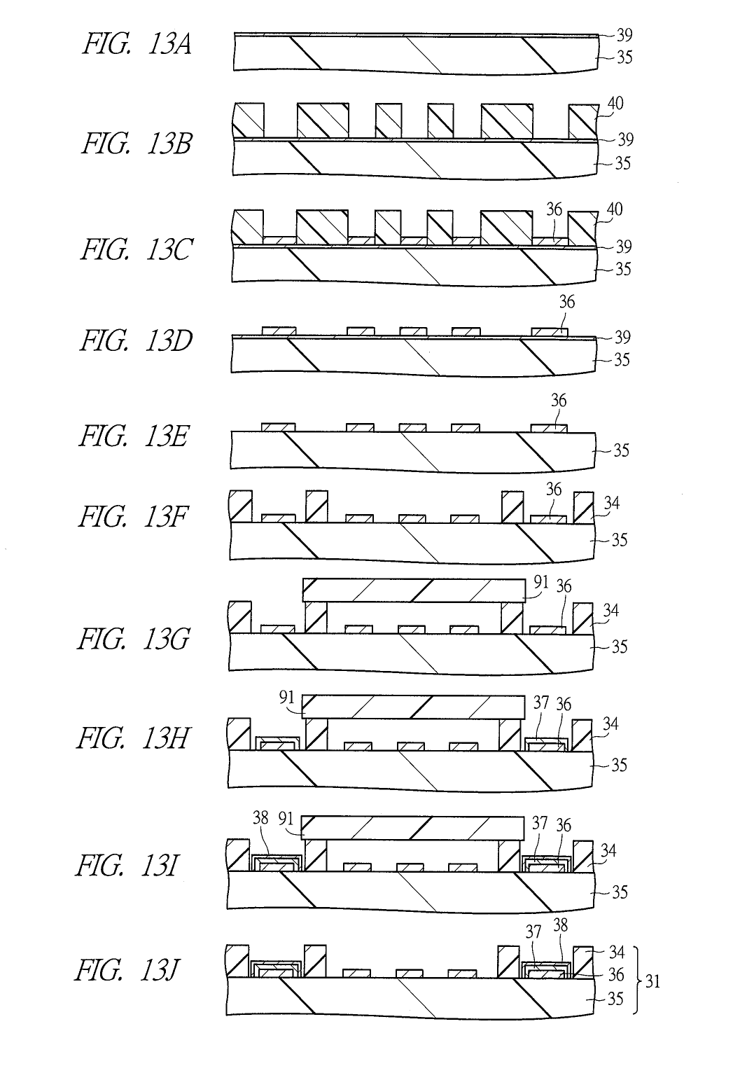

FIG. 9 shows an example in which the present invention is applied to a substrate whose electrode pitch of flip-chip bonding electrodes is 40 μm.

The width of the flip-chip bonding electrode of this substrate was 20 μm. Also, the thickness of a Cu layer 71 was 12 μm, the thickness of a Ni layer 72 thereon was 2 μm, and the thickness of an Au layer 73 on the surface was 0.5 μm. The solder to be used was Sn-3 mass % Ag-0.5 mass % Cu. The solder temperature in the head in the metal jet equipment was 280° C.

Under these conditions, the Sn-3 mass % Ag-0.5 mass % Cu solder 74 having a thickness of about 20 μm was able to be supplied onto the electrode. About 80% of the thickness of the Au layer remained after the bonding, and height variations thereof were also within a permissible range.

Furthermore, an Au bump 75 was flip-chip bonded to the substrate and the bonding part was evaluated with respect to thermal resistance, thermal fatigue reliability, and others in later steps, and as a result, it was confirmed that there was no problem. Also, although wire bonding electrodes had the same structure as the above-described flip-chip bonding electrode and only the electrode widths thereof are different, the wire-bonding connectivity was also good including the shear strength and others.

As described above, by using the electrodes having the same structure obtained by forming a Ni layer on Cu and then forming an Au layer in the periphery thereof, without separately forming the electrodes for wire bonding and flip-chip bonding in two types of plating processes, wire bonding and flip-chip bonding using solder can be carried out without any problem even for the substrate having extremely narrow pitches, and the cost reduction can be achieved.

### Application Example 2 of the Present Invention

FIG. 10 is an example where the present invention is applied to a package having a structure using no Au bump.

The electrode pitch of flip-chip bonding electrodes was 30 μm, and the electrode width thereof was 15 μm. The thickness of a Cu layer 81 was 10 μm, the thickness of a Ni layer 82 thereon was 2 μm, and the thickness of an Au layer 83 on the surface was 0.8 μm. The solder to be used was Sn-0.7 mass % Cu. The solder temperature in the head in the metal jet equipment was 280° C. Also, the plasma treatment was performed to the substrate as a pretreatment of metal jet.

Also in this case, a solder bump 84 having a thickness of 20 μm was able to be formed on the electrode, and height variations thereof were not problematic.

Subsequently, the flip-chip bonding was carried out for an electrode 85 on a chip 86 having a Ni/Au-metalized surface. Then, the wire bonding electrodes were wire-bonded, and it was confirmed that any problem was not caused.

Thus, the present invention can be applied also to a package having a structure using no Au bump.

Although the solder was supplied only to the substrate side in this example, the solder may be supplied also to the electrode 85 of the chip 86 side by metal jet. Alternatively, the solder may be supplied to both the electrode of an interposer substrate 87 and the electrode 85 of the chip 86. Further, the bonding height may be increased.

In the foregoing, the invention made by the inventors of the present invention has been concretely described based on the embodiment. However, it is needless to say that the present invention is not limited to the foregoing embodiments and various modifications and alterations can be made within the scope of the present invention.

### INDUSTRIAL APPLICABILITY

The SiP package to which the present invention is applied is presupposed to be used in portable electronic devices such as cellular phones and digital cameras. However, the usage thereof is not necessarily limited to them.

1. An interposer substrate comprising: a flip-chip bonding electrode formed of a stacked layer of a copper (Cu) layer and a nickel (Ni) layer; and a wire bonding electrode formed of a stacked layer of a copper (Cu) layer and a nickel (Ni) layer,
wherein surfaces of the flip-chip bonding electrode and the wire bonding electrode, the surfaces not being in contact with a base substance or a solder resist, are covered by gold (Au).

2. The interposer substrate according to claim 1,
wherein the Au is supplied by electroless plating.

3. The interposer substrate according to claim 2,
wherein the Cu layer of the flip-chip bonding electrode and the Cu layer of the wire bonding electrode are formed to have an approximately same thickness, and
the Ni layer of the flip-chip bonding electrode and the Ni layer of the wire bonding electrode are formed to have an approximately same thickness.

4. A LSI chip employing SiP (System in Package) using the interposer substrate according to claim 3.

5. The LSI chip according to claim 4,
wherein a metal jet system is used to supply solder for flip-chip bonding of the interposer substrate.

6. An information terminal device comprising the LSI chip according to claim 5.

7. A manufacturing method of an interposer substrate, the interposer substrate comprising: a flip-chip bonding electrode formed of a stacked layer of a copper (Cu) layer and a nickel (Ni) layer; and a wire bonding electrode formed of a stacked layer of a copper (Cu) layer and a nickel (Ni) layer, the manufacturing method comprising:
a seed layer preparation step for preparing a seed layer;
a plating resist formation step for forming a plating resist on the seed layer;
a Cu layer formation step for forming a Cu layer by utilizing the seed layer;
a Ni layer formation step for forming and stacking a Ni layer on the Cu layer;
a seed layer removal step for removing a part of the seed layer on which the Ni layer and the Cu layer are not stacked;
a solder resist formation step for forming a solder resist layer; and
an Au layer formation step for supplying gold (Au) onto exposed surfaces of the Cu layer and the Ni layer,
wherein the flip-chip bonding electrode and the wire bonding electrode are formed without repeating each of the steps.

8. The manufacturing method of the interposer substrate according to claim 7, further comprising:
a plating resist removal step for removing the plating resist after the Ni layer formation step.

9. A manufacturing method of a LSI chip using the interposer substrate according to claim 1, the manufacturing method comprising:
a solder supply step for supplying solder to the flip-chip bonding electrode by a metal jet system;
a first chip bonding step for thermocompression-bonding a first chip to the flip-chip bonding electrode;
a first chip fixing step for filling a resin between the first chip and the interposer substrate and hardening the resin;
a second chip placing step for placing a second chip on the first chip;
a second chip wire bonding step for wire bonding the second chip and the wire bonding electrode; and
a step of bonding a third or more chips by repeating similar steps to those for the bonding of the second chip in accordance with needs.

10. A manufacturing method of a LSI chip using the interposer substrate according to claim 1, comprising:
a solder supply step for supplying solder to the flip-chip bonding electrode by a metal jet system;
a resin supply step for supplying a resin for fixing a first chip;
a first chip bonding/fixing step for thermocompression-bonding the first chip to the flip-chip bonding electrode and hardening the resin;
a second chip placing step for placing a second chip on the first chip;
a second chip wire bonding step for wire bonding the second chip and the wire bonding electrode; and
a step of bonding a third or more chips by repeating similar steps as those for the bonding of the second chip in accordance with needs.
